(19) United States
(12) Patent Application Publication
(10) Pub. No.: US 2011/0084787 A1
(43) Pub. Date: Apr. 14, 2011

(54) PHOTOSENSITIVE RESIN COMPOSITION, METAL-BASE-CONTAINING CIRCUIT BOARD PRODUCTION METHOD EMPLOYING THE PHOTOSENSITIVE RESIN COMPOSITION, AND METAL-BASE-CONTAINING CIRCUIT BOARD

(75) Inventors: Hirofumi Fujii, Osaka (JP); Katsutoshi Hirashima, Osaka (JP); Yasushi Tamura, Osaka (JP)

(73) Assignee: NITTO DENKO CORPORATION, Osaka (JP)

(21) Appl. No.: 12/887,980

(22) Filed: Sep. 22, 2010

(30) Foreign Application Priority Data
Oct. 14, 2009 (JP) 2009-237769

(51) Int. Cl. H01F 10/10; G03F 7/004; G03F 7/20; H05K 1/00

(52) U.S. Cl. 335/296; 430/270.1; 430/312; 174/258

(57) ABSTRACT

A photosensitive resin composition which is capable of reducing stress occurring due to thermal history, such as a heat treatment, a metal-base-containing circuit board production method which suppresses the warpage of a circuit board by employing the photosensitive resin composition and a metal-base-containing circuit board. The photosensitive resin composition comprises a polyamide acid, a 1,4-dihydropyridine derivative and an amide compound.

### BACKGROUND OF THE INVENTION

1. Field of the Invention

The present invention relates to a photosensitive resin composition from which a polyimide coating film pattern can be formed at a higher resolution as having a reduced stress, a metal-base-containing circuit board production method employing the photosensitive resin composition, and a metal-base-containing circuit board.

2. Description of the Related Art

In recent years, hard disk drives (hereinafter sometimes referred to as “HDD”) are required to have a higher capacity and a higher information transmission speed. Such an HDD includes a so-called thin film magnetic head (MRH), and a so-called circuit-containing suspension board which supports the magnetic head.

With a recent rapidly increasing demand for the higher capacity, the HDD is required to access a minute region for reading and writing, so that a distance between the magnetic head and a disk tends to be reduced. For precise control of the distance between the magnetic head and the disk, a polyimide photosensitive material having a lower linear expansion coefficient and a lower hygroscopic expansion coefficient is used instead of a conventional epoxy resin photosensitive material as an insulative resin in formation of wirings.

In recent years, a photosensitive polyimide composition containing a photosensitive agent of 1,4-dihydropyridine derivative is proposed as the polyimide photosensitive material, and becomes dominant (see JP-A-HEI7 (1995)-281441). Conventionally, the photosensitive polyimide composition simply contains a polyimide and a photosensitive agent. Therefore, a resin can be designed according to a metal material to be used for the suspension board and in consideration of required electrical and mechanical properties.

For formation of a minute pattern from the above photosensitive polyimide composition, it is necessary to perform a heat treatment by heating after exposure but before development. Due to the heat treatment, stress is more liable to occur in the pattern formed from the photosensitive polyimide composition than in a pattern formed from a conventional non-photosensitive polyimide material. Therefore, the pattern formed from the photosensitive polyimide composition suffers from various problems such as warpage occurring due to the stress.

In view of the foregoing, it is an object of the present invention to provide a photosensitive resin composition which is capable of reducing stress occurring due to thermal history such as a heat treatment, a metal-base-containing circuit board production method which suppresses the warpage of a circuit board and permits the precise basic design of a circuit board by employing the photosensitive resin composition, and a metal-base-containing circuit board.

### SUMMARY OF THE INVENTION

According to a first aspect of the present invention, there is provided a photosensitive resin composition comprising:

(A) a polyamide acid;
(B) a 1,4-dihydropyridine derivative represented by the following general formula (1):

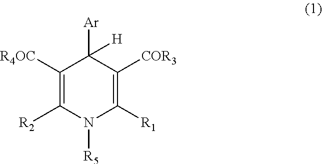

wherein Ar is a monovalent aromatic hydrocarbon group having a nitro group at its ortho position; R₁ and R₂, which may be the same or different, are each a hydrogen atom or a C₁₋₄ alkyl group; R₃ and R₄, which may be the same or different, are each a C₁₋₄ alkyl group or a C₁₋₄ alkoxy group; and R₅ is a hydrogen atom or a C₁₋₄ alkyl group; and
(C) an amide compound represented by the following general formula (2):

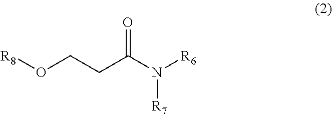

wherein R₆ and R₇ are each a methyl group; and R₈ is a C₁₋₄ alkyl group.

According to a second aspect of the present invention, there is provided a metal-base-containing circuit board production method, which comprises the steps of: forming a first coating film of the above photosensitive resin composition on a metal base; irradiating the first coating film with activation radiation via a first photomask having a first predetermined pattern for exposure, and heat-treating the first coating film at 150° C. to 200° C.; removing an unexposed portion of the first coating film with a developing liquid to form a first negative pattern, and heat-treating a remaining portion of the first coating film at 250° C. to 450° C., whereby the remaining portion of the first coating film is imidized to form a polyimide insulative layer of the first predetermined pattern on the metal base; forming a conductor layer of a predetermined wiring circuit pattern on the insulative layer; forming a second coating film of the above photosensitive resin composition over the conductor layer; irradiating the second coating film with activation radiation via a second photomask having a second predetermined pattern for exposure, and heat-treating the second coating film at 150° C. to 200° C.; and removing an unexposed portion of the second coating film with the developing liquid to form a second negative pattern, and heat-treating a remaining portion of the second coating film at 250° C. to 450° C., whereby the remaining portion of the second coating film is imidized to form a polyimide cover layer of the second predetermined pattern over the conductor layer.

According to a third aspect of the present invention, there is provided a metal-base-containing circuit board produced by the above metal-base-containing circuit board production method.

The inventors of the present invention conducted a series of studies to provide a photosensitive resin composition which is capable of reducing stress as described above. In the studies, the inventors mainly investigated why a metal-base-containing circuit board warps after a coating film of a polyamide acid is formed, dried and heated. As a result, the inventors found that an organic solvent used for a solution of a polyamide acid coating film material causes the warpage. Based on this fact, the inventors further conducted studies and found that, where the amide compound represented by the above general formula (2) is used as a polymerization solvent in a polyamide acid synthesis reaction, it is possible to prevent skinning in the formation of the polyamide acid coating film, to promote the imidization of the coating film around a surface of the coating film and to minimize the residual amount of the polyamide acid after curing, because the amide compound represented by the formula (2) has a higher boiling point and the polyamide acid is highly soluble in the amide compound. This suppresses the warpage of a composite material of the metal base and the polyimide coating film. Thus, the photosensitive resin composition containing the amide compound reduces the stress occurring due to thermal history. As a result, the inventors found that the metal-base-containing circuit board produced by employing the photosensitive resin composition is less susceptible to warpage, and attained the present invention.

According to the present invention, the photosensitive resin composition comprises the polyamide acid (A), the 1,4-dihydropyridine derivative (B) represented by the above general formula (1), and the amide compound (C) represented by the above general formula (2). Wherein the insulative layer and the cover layer of the metal-base-containing circuit board are formed by employing the photosensitive resin composition, it is possible to reduce the stress occurring due to thermal history, such as a heat treatment.

In the metal-base-containing circuit board production method according to the present invention, the first coating film of the photosensitive resin composition is formed on the metal base, and irradiated with the activation radiation via the first photomask having the first predetermined pattern for exposure. After the heat treatment is performed at 150° C. to 200° C., the unexposed portion of the first coating film is removed with the developing liquid, whereby the first negative pattern is formed. Further, the heat treatment is performed at 250° C. to 450° C. to imidize the remaining portion of the first coating film, whereby the polyimide insulative layer of the first predetermined pattern is formed on the metal base. After the conductor layer having the predetermined wiring circuit pattern is formed on the insulative layer, the second coating film of the photosensitive resin composition is formed over the conductor layer, and irradiated with the activation radiation via the second photomask having the second predetermined pattern for exposure. After the heat treatment is performed at 150° C. to 200° C., the unexposed portion of the second coating film is removed with the developing liquid, whereby the second negative pattern is formed. Further, the heat treatment is performed at 250° C. to 450° C. to imidize the remaining portion of the second coating film, whereby the polyimide cover layer of the second predetermined pattern is formed over the conductor layer. Thus, the metal-base-containing circuit board is produced. Since the insulative layer and the cover layer of the metal-base-containing circuit board are formed by using the photosensitive resin composition, the metal-base-containing circuit board is substantially free from warpage and is highly reliable. Therefore, the metal-base-containing circuit board can be precisely designed and controlled as having a three-dimensional configuration. The metal-base-containing circuit board produced by the metal-base-containing circuit board production method according to the present invention is useful as a circuit-containing suspension board for a thin film magnetic head of an HDD or the like.

### DETAILED DESCRIPTION OF THE INVENTION

The present invention will hereinafter be described by way of embodiments thereof. However, it should be understood that the invention is not limited to these embodiments.

### Photosensitive Resin Composition

A photosensitive resin composition according to the present invention is prepared by using a polyamide acid (A), a specific 1,4-dihydropyridine derivative (B), and a specific amide compound (C).

The polyamide acid (A) is also called polyamic acid. The polyamide acid (A) is typically prepared by causing a tetracarboxylic dianhydride component and a diamine component to react with each other in a proper organic solvent, such as N,N-dimethylacetamide, N-methyl-2-pyrrolidone, N,N-dimethylformamide, dimethyl sulfoxide or hexamethylphosphoramide, which serves as a polymerization solvent.

Examples of the tetracarboxylic dianhydride component include 3,3′,4,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 4,4′-oxydiphthalic dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic dianhydride and ethylene glycol bistrimellitic dianhydride, which may be used either alone or in combination.

Examples of the diamine component include 4,4′-diaminodiphenyl ether, 3,4′-diaminodiphenyl ether, 3,3′-diaminodiphenyl ether, m-phenylenediamine, p-phenylenediamine, 1,1′-biphenyl-2,2′-di(trifluoromethyl)-4,4′-diamine, 4,4′-diaminodiphenylpropane, 3,3′-diaminodiphenylpropane, 4,4′-diaminodiphenylmethane, 3,3′-diaminodiphenylmethane, 4,4′-diaminodiphenyl sulfide, 3,3′-diaminodiphenyl sulfide, 4,4′-diaminodiphenyl sulfone, 3,3′-diaminodiphenyl sulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, hexamethylene diamine, 1,8-diaminooctane, 1,12-diaminododecane, 4,4′-diaminobenzophenone and 1,3-bis(3-aminopropyl)-1,1,3,3-tetramethyldisiloxane, which may be used either alone or in combination.

In the present invention, a preferred combination of the tetracarboxylic dianhydride component and the diamine component is such that 3,3′,4,4′-biphenyltetracarboxylic dianhydride as the tetracarboxylic dianhydride component is used in combination with one or two or more of p-phenylenediamine, 4,4′-diaminodiphenyl ether and 1,1′-biphenyl-2,2′-di(trifluoromethyl)-4,4′-diamine as the diamine component.

The specific 1,4-dihydropyridine derivative (B) to be used in combination with the polyamide acid (A) is a 1,4-dihydropyridine derivative represented by the following general formula (1).

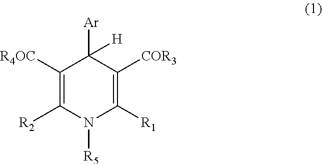

wherein Ar is a monovalent aromatic hydrocarbon group having a nitro group at its ortho position; R₁ and R₂, which may be the same or different, are each a hydrogen atom or a C₁₋₄ alkyl group; R₃ and R₄, which may be the same or different, are each a C₁₋₄ alkyl group or a C₁₋₄ alkoxy group; and R₅ is a hydrogen atom or a C₁₋₄ alkyl group.

Specific examples of the 1,4-dihydropyridine derivative represented by the above formula (1) include 1-ethyl-3,5-dimethoxycarbonyl-4-(2-nitrophenyl)-1,4-dihydropyridine, 1,2,6-trimethyl-3,5-dimethoxycarbonyl-4-(2-nitrophenyl)-1,4-dihydropyridine, 2,6-dimethyl-3,5-diacetyl-4-(2-nitrophenyl)-1,4-dihydropyridine and 1-carboxyethyl-3,5-dimethoxycarbonyl-4-(2-nitrophenyl)-1,4-dihydropyridine, which may be used either alone or in combination. Of the 1,4-dihydropyridine derivatives represented by the above formula (1), 1-ethyl-3,5-dimethoxycarbonyl-4-(2-nitrophenyl)-1,4-dihydropyridine is particularly preferred in the present invention.

In the inventive photosensitive resin composition, the 1,4-dihydropyridine derivative (B) represented by the above formula (1) is typically present in a proportion of 5 to 25 parts by weight (hereinafter referred to simply as “parts”), particularly preferably 10 to 15 parts, based on a total of 100 parts of the tetracarboxylic dianhydride component and the diamine component as ingredients of the polyamide acid (A). In other words, the 1,4-dihydropyridine derivative (B) is preferably present in a proportion of 30 to 70 wt %, particularly preferably 50 to 60 wt %, based on the overall weight of the photosensitive resin composition. If the proportion of the 1,4-dihydropyridine derivative (B) is too high, a polyimide coating film formed from the resulting photosensitive resin composition tends to have poorer physical properties. If the proportion of the 1,4-dihydropyridine derivative (B) is too low, the resulting photosensitive resin composition tends to have poorer patternability.

The specific amide compound (C) to be used in combination with the above polyamide acid (A) and the specific 1,4-dihydropyridine derivative (B) is an amide compound represented by the following general formula (2):

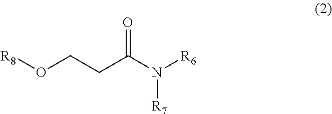

wherein R₆ and R₇ are each a methyl group, and R₈ is a C₁₋₄ alkyl group.

In the above formula (2), it is particularly preferred that R₆ and R₇ are each a methyl group, and R₈ is n-butyl group.

An example of the specific amide compound (C) is N,N-dimethyl-2-(n-butyloxy)acetamide. An example of the amide compound (C) is an amide solvent available from Idemitsu Petrochemical Co., Ltd.

In the inventive photosensitive resin composition, the specific amide compound (C) serves as a polymerization solvent for synthesis of the polyamide acid (A) using the tetracarboxylic dianhydride component and the diamine component. Where the amide compound (C) is used in combination with other polymerization solvent for the synthesis of the polyamide acid, the amide compound (C) is preferably present in a proportion of 20 to 80 wt %, particularly preferably 30 to 60 wt %, based on the total weight of the polymerization solvents. Examples of the polymerization solvent to be used in combination with the amide compound (C) include N,N-dimethylacetamide, N-methyl-2-pyrrolidone, N,N-dimethylformamide, dimethyl sulfoxide and hexamethylphosphoramide.

The inventive photosensitive resin composition may contain additives such as a solubility controlling agent for controlling the solubility of the photosensitive resin composition in a developing liquid and a basic catalyst for promoting imidization, as required, in addition to the components (A) to (C).

Examples of the solubility controlling agent include imide acrylate compounds represented by the following general formula (a):

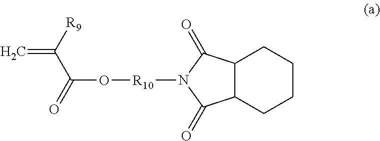

wherein R₉ is a hydrogen atom or a methyl group, and R₁₀ is a divalent hydrocarbon group having a carbon number of not less than 2.

In the above general formula (a), R₁₀ is preferably a C₂₋₈ alkylene group, particularly preferably an ethylene group. A specific example of the solubility controlling agent is N-acryloyloxyethylhexahydrophthalimide.

Examples of the basic catalyst for promoting the imidization include imidazoles.

The inventive photosensitive resin composition is prepared, for example, in the following manner. The tetracarboxylic dianhydride component and the diamine component as the ingredients of the polyamide acid (A) are caused to react with each other in the organic solvent to prepare a polyamide acid solution. Then, the specific 1,4-dihydropyridine derivative (B) represented by the above general formula (1), the amide compound (C) represented by the above general formula (2) and other optional additives are mixed and dissolved in the polyamide acid solution to prepare a solution of the photosensitive resin composition. Alternatively, the tetracarboxylic dianhydride component and the diamine component as the ingredients of the polyamide acid (A) are caused to react with each other in a solvent mixture containing the amide compound (C) represented by the above general formula (2) and other organic solvent to prepare a polyamide acid solution. Then, the specific 1,4-dihydropyridine derivative (B) represented by the above general formula (1) and other optional additives are mixed and dissolved in the polyamide acid solution to prepare a solution of the photosensitive resin composition.

The inventive photosensitive resin composition thus prepared preferably has a hygroscopic expansion coefficient of 0 to 20 ppm/% RH, more preferably 0 to 10 ppm/% RH, and a linear expansion coefficient of 0 to 30 ppm/° C., more preferably 0 to 20 ppm/° C. If the linear expansion coefficient and the hygroscopic expansion coefficient of the photosensitive resin composition fall outside the aforesaid ranges, there are significant differences in linear expansion coefficient and hygroscopic expansion coefficient between the photosensitive resin composition and a metal material. Therefore, the resulting metal-base-containing circuit board is liable to suffer from warpage which occurs due to interlayer stress or the like.

The linear expansion coefficient is measured, for example, in the following manner. A polyimide film is formed from the photosensitive resin composition, and a measurement sample having a width of 5 mm and a length of 25 mm is cut out of the polyimide film. The linear expansion coefficient of the measurement sample is measured by means of a thermomechanical analyzer (THERMO PLUS TMA8310 available from Rigaku Corporation). More specifically, linear expansion coefficients of the measurement sample are measured in a temperature range of 50° C. to 200° C. with a load of 5 g with a measurement length (inter-chuck distance) of 20 mm, while the temperature is increased at a rate of 10° C./min. Then, an average of the linear expansion coefficients is determined.

The hygroscopic expansion coefficient is measured, for example, in the following manner. A polyimide film is formed from the photosensitive resin composition, and a measurement sample having a width of 5 mm and a length of 25 mm is cut out of the polyimide film. The hygroscopic expansion coefficient of the measurement sample is measured by means of a humidity-variable mechanical analyzer (THERMO PLUS TMA8310+HUM1 available from Rigaku Corporation). More specifically, hygroscopic expansion coefficients of the measurement sample are measured at a temperature of 30° C. with a load of 5 g with a measurement length (inter-chuck distance) of 20 mm, while the relative humidity is changed in increments of 20% RH from 20% RH to 80% RH. Then, an average of the hygroscopic expansion coefficients is determined.

### Pattern Formation Method

An exemplary method for forming a pattern of a polyimide coating film by using the inventive photosensitive resin composition will be described below.

First, the polyamide acid (A) is synthesized by causing the tetracarboxylic dianhydride component and the diamine component to react with each other in the polymerization solvent (organic solvent) containing the amide compound (C), and the 1,4-dihydropyridine derivative (B) is mixed and dissolved in the resulting solution of the polyamide acid (A). Thus, the inventive photosensitive resin composition is prepared. Then, the photosensitive resin composition is applied onto a surface of a metal base (e.g., an aluminum plate, a stainless plate or an alloy plate) by a comma coating method or a fountain coating method, and dried. Thus, a coating film of the photosensitive resin composition is formed. The dry thickness of the coating film is preferably 1 to 40 μm, particularly preferably 5 to 25 μm.

Examples of the polymerization solvent (organic solvent) to be used in combination with the amide compound (C) include, as described above, N-methyl-2-pyrrolidone, N,N-dimethylacetamide, N,N-dimethylformamide, dimethyl sulfoxide and hexamethylphosphoramide, which may be used either alone or in combination.

The coating film thus formed is dried (e.g., at 80° C. for about 10 minutes), and then exposed to activation radiation such as ultraviolet radiation via a photomask having a predetermined pattern. After the exposure, the resulting film is heat-treated at a temperature of 150° C. to 200° C. for 1 to 20 minutes, preferably at 170° C. to 200° C. for about 10 minutes, more preferably at 180° C. to 190° C. for about 10 minutes (post-exposure heat treatment). Thereafter, the resulting film is developed to remove an unexposed portion thereof by a dipping method, a spray method, a puddle method or the like. A developing liquid to be used for the development is preferably capable of completely dissolving away the unexposed portion of the film subjected to the exposure within a proper period. Examples of the developing liquid include inorganic alkaline aqueous solutions such as of sodium hydroxide and potassium hydroxide, and organic alkaline aqueous solutions, such as propylamine, butylamine, monoethanolamine, tetramethylammonium hydroxide and choline, which may be used either alone or in combination. As required, the alkaline aqueous solution may further contain a solubility controlling agent such as an alcohol, and a surface active agent. A temperature for the development may be around room temperature (i.e., about 25° C.±10° C.) or, as required, the developing liquid may be heated.

After the development, the resulting film is rinsed with a rinse liquid, whereby a desired negative pattern image is provided.

Examples of the activation radiation to be used for the exposure include ultraviolet radiation and electron radiation. Various types of light sources are usable for the activation radiation, and examples of the light sources include a carbon arc lamp, a mercury vapor arc lamp, an ultrahigh pressure mercury lamp, a high pressure mercury lamp and a xenon lamp which are capable of effectively emitting ultraviolet radiation, and a photoflood lamp and a solar lamp which are capable of effectively emitting visible light.

For irradiation with the activation radiation, the exposure wavelength is typically 300 to 450 nm, preferably 360 to 440 nm, and the cumulative dose of the activation radiation is typically 100 to 1000 mJ/cm², preferably 150 to 600 mJ/cm².

The pattern image thus formed is heat-treated for polyimidization, whereby a polyimide precursor as a skeletal material is cyclodehydrated into a less soluble polyimide. Therefore, the negative pattern image is free from swelling with the developing liquid, and excellent in resolution.

A heating temperature for the polyimidization is typically 250° C. to 450° C., preferably 300° C. to 400° C. If the heating temperature is too low, the 1,4-dihydropyridine derivative (B) remains in the resulting polyimide coating film and, therefore, the polyimide coating film fails to have desired physical properties. On the other hand, if the heating temperature is too high, the polyimide coating film tends to be degraded.

The post-exposure heat treatment reduces the solubility of an exposed portion of the coating film of the inventive photosensitive resin composition in the developing liquid as compared with the solubility of the unexposed portion of the coating film. Therefore, the coating film is formed as having a negative latent image. The coating film having the negative latent image is treated with the alkaline aqueous solution, whereby the unexposed portion is dissolved away for the development. Thus, the negative pattern image is formed. Thereafter, the negative pattern image is heated to a higher temperature in an atmosphere of an inert gas such as nitrogen or in vacuum, whereby the polyamide acid forming the negative pattern image is subjected to a ring closure reaction to be imidized. At the same time, the 1,4-dihydropyridine derivative (B) serving as a photosensitive agent in the negative pattern image is thermally decomposed to be volatilized. Thus, the negative pattern of the polyimide coating film can be provided.

### Metal-Base-Containing Circuit Board Production Method

A metal-base-containing circuit board production method will be described, which utilizes the method for forming the pattern of the polyimide coating film.

First, a coating film of the photosensitive resin composition is formed on a metal base, then irradiated with the activation radiation via a photomask having a predetermined pattern for exposure, and heat-treated at 150° C. to 200° C. (post-exposure heat treatment). Then, an unexposed portion of the coating film is removed with the use of the developing liquid to form a negative pattern, and a remaining portion of the coating film is heat-treated at 250° C. to 450° C. Thus, the remaining portion of the coating film is imidized to form a polyimide insulative layer of the predetermined pattern on the metal base. Subsequently, a conductor layer having a wiring circuit pattern is formed on the insulative layer through a known patterning method such as a semi-additive method. In substantially the same manner as in the formation of the insulative layer, a coating film of the photosensitive resin composition is formed over the conductor layer by the aforesaid method, then irradiated with the activation radiation via a photomask having a predetermined pattern for exposure, and heat-treated at 150° C. to 200° C. (post-exposure heat treatment). Then, an unexposed portion of the coating film is removed with the use of the developing liquid to form a negative pattern, and a remaining portion of the coating film is heat-treated at 250° C. to 450° C. Thus, the remaining portion of the coating film is imidized to form a polyimide cover layer of a predetermined pattern over the conductor layer. Thus, a metal-base-containing circuit board is produced.

The semi-additive method employed for the formation of the conductor layer is a kind of an additive method in which a metal is deposited over the resin layer (insulative layer) by an electroless plating method and then a wiring pattern portion is formed by an electrolytic plating method and/or an etching method to form an electrically isolated conductor pattern having a predetermined overall conductor thickness. More specifically, as stated in JP-A-2001-350272, an underlying thin conductor film is formed on the insulative layer serving as a base layer, and then a plating resist film having a pattern reverse to a predetermined wiring circuit pattern is formed on the underlying layer. Thereafter, a conductor layer of the wiring circuit pattern is formed on a surface portion of the underlying layer not formed with the plating resist film by plating. Then, the plating resist film and a portion of the underlying layer formed with the plating resist film are removed. Thus, the conductor layer of the wiring circuit pattern is formed.

Examples of the metal base include an aluminum plate, a stainless plate, a 42-alloy plate and other types of alloy plates. Exemplary materials for the conductor layer include electrically conductive metal materials such as copper, nickel, gold and solder, and alloys of any of these metals.

The metal base typically has a thickness of 10 to 30 μm, preferably 15 to 25 μm. The conductor layer typically has a thickness of 3 to 25 μm, preferably 5 to 20 μm. The insulative layer typically has a thickness of 5 to 15 μm, preferably 8 to 12 μm. The cover layer typically has a thickness of 2 to 10 μm, preferably 3 to 7 μm.

Thereafter, the polyimide cover layer is subjected to a polyimide (PI) etching process so as to have a desired shape (thickness). In the PI etching process, for example, the board is dipped in a 20% ethanolamine solution of NaOH contained in a bath kept at a temperature of about 60° C. to about 90° C.

The metal-base-containing circuit board thus produced is useful, for example, as a circuit-containing suspension board for a thin film magnetic head.

### EXAMPLES

Inventive examples will be described in conjunction with comparative examples. However, it should be understood that the present invention is not limited to these inventive examples.

### Example 1

In a solvent mixture containing 802 g of N-methyl-2-pyrrolidone (NMP) and 802 g of an amide compound represented by the following structural formula (3) (amide solvent available from Idemitsu Petrochemical Co., Ltd.), 62.5 g of p-phenylenediamine and 20.4 g of 4,4′-diaminodiphenyl ether were caused to react with 200 g of 3,3′,4,4′-biphenyltetracarboxylic dianhydride at a room temperature (25° C.). Thus, a solution of a polyamide acid was prepared.

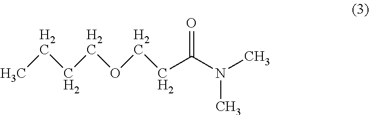

In this polyamide acid solution, 28.3 g of 1-ethyl-3,5-dimethoxycarbonyl-4-(2-nitrophenyl)-1,4-dihydropyridine represented by the following structural formula (4) and 42.3 g of N-acryloyloxyethylhexahydrophthalimide as a development acceleration agent were dissolved. Thus, a photosensitive resin composition was prepared in the form of a homogeneous solution.

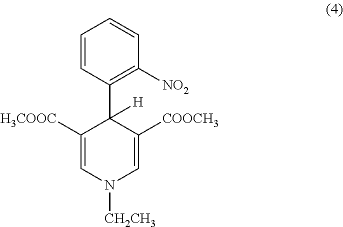

Subsequently, the photosensitive resin composition solution was applied onto an 18-μm thick SUS304 foil at a coating rate of 1.2 m/min at a drying temperature of 120° C. by means of a coating machine having a 4-m long drying oven. Thus, a polyamide acid coating film having a dry thickness of about 20-μm was formed. Then, the polyamide acid coating film was exposed to radiation emitted at a cumulative dose of 200 mJ/cm² from a 500-W ultrahigh-pressure mercury lamp via a photomask, and then subjected to a post-exposure heat treatment at 180° C. at 3.5 m/min in the drying oven of the coating machine. In turn, an unexposed portion of the coating film was dissolved away at a temperature of 40° C. at a pressure of 0.1 MPa with the use of a water/ethanol (a weight ratio of 1/1) solution containing tetramethylammonium hydroxide at a concentration of 5 wt %, and rinsed with water. Thus, a negative polyamide acid pattern having a thickness of 10 μm was formed.

The negative polyamide acid pattern thus formed was heated at 380° C. for 2 hours in a nitrogen atmosphere to be thereby imidized. Thus, a minute pattern of a polyimide coating film was formed. For determination of resolution, 10-μm, 20-μm, 30-μm, 40-μm, 50-μm, 70-μm, 90-μm and 100-μm square via-patterns were used. The resolution was determined based on a minimum via-pattern size which ensured an opening percentage of not less than 50%. The results are shown in Table 1.

In substantially the same manner, a 10-μm thick polyimide coating film was formed on a SUS304 foil by entirely exposing a polyamide acid coating film without the photomask. The warpage of a composite material including the SUS304 foil and the polyimide coating film, the absorption intensity at a surface of the polyimide coating film and the absorption intensity at an inside of the polyimide coating film were measured in the following manner. The results are shown in Table 1.

### Warpage

A 10-cm square sample was cut out of the composite material of the SUS304 foil and the polyimide coating film produced in the aforesaid manner, and placed on a measurement base with its SUS304 foil facing down. In this state, the heights of four corners of the sample were measured, and an average of the heights was calculated to be defined as the warpage. Where the sample was warped with its four corners upward on the side of the polyimide coating film, a plus (+) sign is prefixed to a numeral in Table 1. Where the sample was warped with its four corners downward on the side of the SUS304 foil, a minus (−) sign is prefixed to a numeral in Table 1. A steady state warpage was measured after the sample was allowed to stand at a temperature of 23° C. at a humidity of 30% for 3 hours in an environmental tester. A dry warpage was measured after the sample was allowed to stand at 100° C. for 1 hour in an oven.

### Intensity of Absorption by Imide Group

A sample was prepared by cutting the 10-μm thick polyimide coating film of the above composite material including the SUS304 foil and the polyimide coating film at an angle of about 1 degree, then fixed to a base and subjected to an ATR mapping measurement by a microscopic infrared ATR method. By using NICOLET 4700+Continupm available from Thermo Fisher Scientific K.K., FT-IR spectra were obtained at a resolution of 8 cm⁻¹ with a cumulative number of 32 in 10-μm and 20-μm steps (line maps) with a detector MCT/A. The intensity ratios of the absorption by the imide group at a surface of the sample (at a depth of 2 μm) and at an inside of the sample (at a depth of 10 μm) were each determined in the form of a 1770 cm⁻¹/1515 cm⁻¹ absorbance ratio for comparison.

On the other hand, the linear expansion coefficient and the hygroscopic expansion coefficient of the formed polyimide coating film were determined in the following manner. The results are shown in Table 1.

### Linear Expansion Coefficient

The SUS304 foil was etched off from the above polyimide coating film formed thereon with a solution of ferric chloride. In turn, an evaluation sample having a width of 5 mm and a length of 25 mm was cut out of the resulting polyimide film. Then, the linear expansion coefficient of the sample was measured with the use of a thermomechanical analyzer (THERMO PLUS TMA8310 available from Rigaku Corporation). More specifically, linear expansion coefficients of the sample were measured in a temperature range of 50° C. to 200° C. with a load of 50 g with a measurement length (inter-chuck distance) of 20 mm, while the temperature was increased at a rate of 10° C./min. Then, an average of the linear expansion coefficients was determined.

### Hygroscopic Expansion Coefficient

The SUS304 foil was etched off from the above polyimide coating film formed thereon with a solution of ferric chloride. In turn, an evaluation sample having a width of 5 mm and a length of 25 mm was cut out of the resulting polyimide film. The hygroscopic expansion coefficient of the sample was measured with the use of a humidity-variable mechanical analyzer (THERMO PLUS TMA8310+HUM1 available from Rigaku Corporation). More specifically, hygroscopic expansion coefficients of the sample were measured at a temperature of 30° C. with a load of 5 g with a measurement length (inter-chuck distance) of 20 mm, while the relative humidity is changed in increments of 20% RH from 20% RH to 80% RH. Then, an average of the hygroscopic expansion coefficients was determined.

### Example 2

A photosensitive resin composition was prepared in substantially the same manner as in Example 1, except that 1-methyl-3,5-di(t-butoxycarbonyl)-4-(2-nitrophenyl)-1,4-dihydropyridine was employed instead of 1-ethyl-3,5-dimethoxycarbonyl-4-(2-nitrophenyl)-1,4-dihydropyridine. Then, the photosensitive resin composition was evaluated for the resolution, the warpage on the SUS304 foil, the imide absorption intensities at the surface and the inside of the polyimide coating film, the linear expansion coefficient and the hygroscopic expansion coefficient by performing measurement in the same manner as in Example 1.

### Example 3

In a solvent mixture containing 85.7 g of NMP and 857 g of the amide compound represented by the above structural formula (3) (amide solvent available from Idemitsu Petrochemical Co., Ltd.), 58.8 g of p-phenylenediamine and 43.5 g of 1,1′-biphenyl-2,2′-di(trifluoromethyl)-4,4′-diamine were caused to react with 200 g of 3,3′,4,4′-biphenyltetracarboxylic dianhydride at a room temperature (25° C.). Thus, a solution of a polyamide acid was prepared.

A photosensitive resin composition was prepared in the form of a homogeneous solution in substantially the same manner as in Example 1, except that the polyamide acid solution thus prepared was used. Then, the photosensitive resin composition was evaluated for the resolution, the warpage on the SUS304 foil, the imide absorption intensities at the surface and the inside of the polyimide coating film, the linear expansion coefficient and the hygroscopic expansion coefficient by performing measurement in the same manner as in Example 1.

### Example 4

In a solvent mixture containing 1203 g of NMP and 401 g of the amide compound represented by the above structural formula (3) (amide solvent available from Idemitsu Petrochemical Co., Ltd.), 62.5 g of p-phenylenediamine and 20.4 g of 4,4′-diaminodiphenyl ether were caused to react with 200 g of 3,3′,4,4′-biphenyltetracarboxylic dianhydride at a room temperature (25° C.). Thus, a solution of a polyamide acid was prepared.

A photosensitive resin composition was prepared in the form of a homogeneous solution in substantially the same manner as in Example 1, except that the polyamide acid solution thus prepared was used. Then, the photosensitive resin composition was evaluated for the resolution, the warpage on the SUS304 foil, the imide absorption intensities at the surface and the inside of the polyimide coating film, the linear expansion coefficient and the hygroscopic expansion coefficient by performing measurement in the same manner as in Example 1.

### Example 5

In a solvent mixture containing 1404 g of NMP and 200 g of the amide compound represented by the above structural formula (3) (amide solvent available from Idemitsu Petrochemical Co., Ltd.), 62.5 g of p-phenylenediamine and 20.4 g of 4,4′-diaminodiphenyl ether were caused to react with 200 g of 3,3′,4,4′-biphenyltetracarboxylic dianhydride at a room temperature (25° C.). Thus, a solution of a polyamide acid was prepared.

A photosensitive resin composition was prepared in the form of a homogeneous solution in substantially the same manner as in Example 1, except that the polyamide acid solution thus prepared was used. Then, the photosensitive resin composition was evaluated for the resolution, the warpage on the SUS304 foil, the imide absorption intensities at the surface and the inside of the polyimide coating film, the linear expansion coefficient and the hygroscopic expansion coefficient by performing measurement in the same manner as in Example 1.

### Comparative Example 1

In a solvent mixture containing 1972 g of NMP, 58.8 g of p-phenylenediamine and 43.5 g of 1,1′-biphenyl-2,2′-di(trifluoromethyl)-4,4′-diamine were caused to react with 200 g of 3,3′,4,4′-biphenyltetracarboxylic dianhydride at a room temperature (25° C.). Thus, a solution of a polyamide acid was prepared.

A photosensitive resin composition was prepared in the form of a homogeneous solution in substantially the same manner as in Example 1, except that the polyamide acid solution thus prepared was used. Then, the photosensitive resin composition was evaluated for the resolution, the warpage on the SUS304 foil, the imide absorption intensities at the surface and the inside of the polyimide coating film, the linear expansion coefficient and the hygroscopic expansion coefficient by performing measurement in the same manner as in Example 1.

The results of the measurement and the evaluation on these examples and comparative examples are shown in Table 1.

TABLE 1

| | | | | | | Compar- |
|---|---|---|---|---|---|---|
| | Ex- | Ex- | Ex- | Ex- | Ex- | ative |
| | ample | ample | ample | ample | ample | Ex- |
| | 1 | 2 | 3 | 4 | 5 | ample 1 |
| Resolution | 20 | 20 | 20 | 20 | 20 | 20 |
| (μm) | | | | | | |
| Thermal | 17 | 17 | 15 | 16 | 15 | 15 |
| expansion | | | | | | |
| coefficient | | | | | | |
| (ppm/° C.) | | | | | | |
| Hygroscopic | 13 | 12 | 6 | 7 | 7 | 7 |
| expansion | | | | | | |
| coefficient | | | | | | |
| (ppm/% RH) | | | | | | |

Intensities of absorption by imide group

| | | | | | | |
|---|---|---|---|---|---|---|
| Inside | 0.63 | 0.64 | 0.64 | 0.63 | 0.63 | 0.63 |
| Surface | 0.62 | 0.62 | 0.64 | 0.64 | 0.64 | 0.59 |
| Steady state | 1 | 0 | −2 | −1 | 0 | 12 |
| warpage (mm) | | | | | | |
| Dry warpage | 3 | 2 | −1 | 0 | 2 | 18 |
| (mm) | | | | | | |

As apparent from the results shown above, the photosensitive resin compositions of Examples 1 to 5 prepared by employing the 1,4-dihydropyridine derivative represented by the structural formula (4) as the photosensitive agent and the amide compound represented by the structural formula (3) as the solvent were each excellent with smaller steady state warpage and smaller dry warpage. The polyimide resin films of Examples 1 to 5 each had a lower linear expansion coefficient and a lower hygroscopic expansion coefficient.

On the other hand, the photosensitive resin composition of Comparative Example 1 prepared by employing NMP alone as the solvent for the synthesis of the polyamide acid was poorer in warpage suppressing effect with greater steady state warpage and greater dry warpage.

### Production of Metal-Base-Containing Circuit Board

By employing the photosensitive resin compositions prepared in Examples 1 to 5, metal-base-containing circuit boards were each produced by the method described above. First, a coating film of the photosensitive resin composition was formed on a SUS304 foil (having a thickness of 19 μm) by means of a coating machine, then irradiated with ultraviolet radiation emitted from a 500-W ultrahigh-pressure mercury lamp at a cumulative dose of 200 mJ/cm² via a photomask having a predetermined pattern for exposure, and heat-treated at 180° C. (post-exposure heat treatment).

In turn, an unexposed portion of the coating film was dissolved away at a temperature of 40° C. at a pressure of 0.1 MPa with the use of a water/ethanol (a weight ratio of 1/1) solution containing tetramethylammonium hydroxide at a concentration of 5 wt %, and rinsed with water to form a 13-μm thick negative pattern. Then, a remaining portion of the coating film was heat-treated at 380° C. Thus, the remaining portion of the coating film was imidized to form a 10-μm thick polyimide insulative layer of the predetermined pattern on the SUS304 foil.

Subsequently, a 10-μm thick conductor layer of copper having a wiring circuit pattern was formed on the insulative layer by the aforesaid semi-additive method. In the same manner as in the formation of the insulative layer, a coating film of the photosensitive resin composition is formed over the conductor layer by the aforesaid method, then irradiated with ultraviolet radiation emitted from a 500-W ultrahigh-pressure mercury lamp at a cumulative dose of 200 mJ/cm² via a photomask having a predetermined pattern for exposure, and heat-treated at 180° C. (post-exposure heat treatment).

Thereafter, an unexposed portion of the coating film was removed with the use of the same developing liquid as described above to form a negative pattern, and a remaining portion of the coating film was heat-treated at 380° C. Thus, the remaining portion of the coating film was imidized to form a 5-μm thick polyimide cover layer of the predetermined pattern over the conductor layer. Thus, the metal-base-containing circuit board is produced.

The metal-base-containing circuit boards thus produced by using the photosensitive resin compositions of Examples 1 to 5 were highly reliable with little warpage.

The inventive photosensitive resin composition suppresses stress which may otherwise occur due to thermal history. The inventive metal-base-containing circuit board produced by using the photosensitive resin composition is substantially free from warpage and is useful, for example, as a circuit-containing suspension board for a thin film magnetic head for an HDD.

Although a specific form of embodiment of the instant invention has been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention.

What is claimed is:

1. A photosensitive resin composition comprising:
(A) a polyamide acid;
(B) a 1,4-dihydropyridine derivative represented by the following general formula (1): 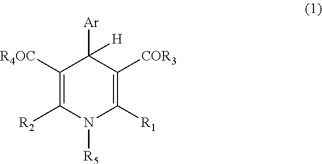
wherein Ar is a monovalent aromatic hydrocarbon group having a nitro group at its ortho position; R₁ and R₂, which may be the same or different, are each a hydrogen atom or a C₁₋₄ alkyl group; R₃ and R₄, which may be the same or different, are each a C₁₋₄ alkyl group or a C₁₋₄ alkoxy group; and R₅ is a hydrogen atom or a C₁₋₄ alkyl group; and
(C) an amide compound represented by the following general formula (2): 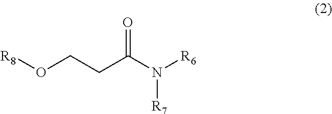
wherein R₆ and R₇ are each a methyl group; and R₈ is a C₁₋₄ alkyl group.

2. The photosensitive resin composition as set forth in claim 1, wherein the amide compound (C) is present in a proportion of 10 to 80 wt % based on an overall weight of the photosensitive resin composition.

3. A metal-base-containing circuit board production method comprising:
forming a first coating film of a photosensitive resin composition on a metal base;
irradiating the first coating film with activation radiation via a first photomask having a first predetermined pattern for exposure, and heat-treating the first coating film at 150° C. to 200° C.;
removing an unexposed portion of the first coating film with a developing liquid to form a first negative pattern, and heat-treating a remaining portion of the first coating film at 250° C. to 450° C., whereby the remaining portion of the first coating film is imidized to form a polyimide insulative layer of the first predetermined pattern on the metal base;
forming a conductor layer of a predetermined wiring circuit pattern on the insulative layer;
forming a second coating film of the photosensitive resin composition over the conductor layer;
irradiating the second coating film with activation radiation via a second photomask having a second predetermined pattern for exposure, and heat-treating the second coating film at 150° C. to 200° C.; and
removing an unexposed portion of the second coating film with the developing liquid to form a second negative pattern, and heat-treating a remaining portion of the second coating film at 250° C. to 450° C., whereby the remaining portion of the second coating film is imidized to form a polyimide cover layer of the second predetermined pattern over the conductor layer;
wherein the photosensitive resin composition comprises:
(A) a polyamide acid;
(B) a 1,4-dihydropyridine derivative represented by the following general formula (1): 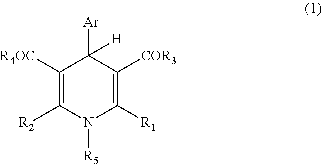
wherein Ar is a monovalent aromatic hydrocarbon group having a nitro group at its ortho position; R₁ and R₂, which may be the same or different, are each a hydrogen atom or a C₁₋₄ alkyl group; R₃ and R₄, which may be the same or different, are each a C₁₋₄ alkyl group or a C₁₋₄ alkoxy group; and R₅ is a hydrogen atom or a C₁₋₄ alkyl group; and
(C) an amide compound represented by the following general formula (2): 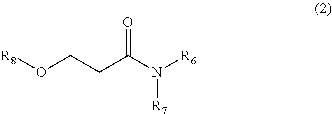
wherein R₆ and R₇ are each a methyl group; and R₈ is a C₁₋₄ alkyl group.

4. A metal-base-containing circuit board produced by the method of claim 3.

5. A circuit-containing suspension board for a thin film magnetic head comprising the metal-base-containing circuit board according to claim 4.

6. The metal-base-containing circuit board production method according to claim 3, wherein the amide compound (C) is in a proportion of 10 to 80 wt % based on an overall weight of the photosensitive resin composition.

7. The photosensitive resin composition according to claim 1, wherein the polyamide acid (A) is produced by reacting a 3,3′,4,4′-biphenyltetracarboxylic dianhydride with one or more of p-phenylenediamine, 4,4′-diaminodiphenyl ether and 1,1′-biphenyl-2,2′-di(trifluoromethyl)-4,4′-diamine.

8. The photosensitive resin composition according to claim 1, wherein the 1,4-dihydropyridine derivative (B) is selected from the group consisting of 1-ethyl-3,5-dimethoxycarbonyl-4-(2-nitrophenyl)-1,4-dihydropyridine, 1,2,6-trimethyl-3,5-dimethoxycarbonyl-4-(2-nitrophenyl)-1,4-dihydropyridine, or 2,6-dimethyl-3,5-diacetyl-4-(2-nitrophenyl)-1,4-dihydropyridine and 1-carboxyethyl-3,5-dimethoxycarbonyl-4-(2-nitrophenyl)-1,4-dihydropyridine.

9. The photosensitive resin composition as set forth in claim 1, wherein the 1,4-dihydropyridine derivative (B) is present in a proportion of 30 to 70 wt % based on an overall weight of the photosensitive resin composition.

10. The photosensitive resin composition as set forth in claim 1, wherein in the amide compound (C) R₆ and R₇ are each a methyl group and R₈ is a n-butyl group.

11. The photosensitive resin composition according to claim 1, further comprising a solubility controlling agent.

12. The photosensitive resin composition according to claim 1, further comprising a catalyst.

13. The metal-base-containing circuit board production method according to claim 3, wherein the polyamide acid (A) is achieved by reacting a 3,3′,4,4′-biphenyltetracarboxylic dianhydride with one or more of p-phenylenediamine, 4,4′-diaminodiphenyl ether and 1,1′-biphenyl-2,2′-di(trifluoromethyl)-4,4′-diamine.

14. The metal-base-containing circuit board production method according to claim 3, wherein the 1,4-dihydropyridine derivative (B) is selected from the group consisting of 1-ethyl-3,5-dimethoxycarbonyl-4-(2-nitrophenyl)-1,4-dihydropyridine, 1,2,6-trimethyl-3,5-dimethoxycarbonyl-4-(2-nitrophenyl)-1,4-dihydropyridine, or 2,6-dimethyl-3,5-diacetyl-4-(2-nitrophenyl)-1,4-dihydropyridine and 1-carboxyethyl-3,5-dimethoxycarbonyl-4-(2-nitrophenyl)-1,4-dihydropyridine.

15. The metal-base-containing circuit board production method according to claim 3, wherein the 1,4-dihydropyridine derivative (B) is present in a proportion of 30 to 70 wt % based on an overall weight of the photosensitive resin composition.

16. The metal-base-containing circuit board production method according to claim 3, wherein in the amide compound (C) R₆ and R₇ are each a methyl group and R₈ is a n-butyl group.

17. The metal-base-containing circuit board production method according to claim 3, further comprising a solubility controlling agent.

18. The metal-base-containing circuit board production method according to claim 3, further comprising a catalyst.
